(19) United States
(12) Patent Application Publication
(10) Pub. No.: US 2026/0271670 A1
(43) Pub. Date: Sep. 10, 2026

(54) PROCESSING CHAMBER AND SEMICONDUCTOR PROCESSING EQUIPMENT

(71) Applicant: BEIJING NAURA MICROELECTRONICS EQUIPMENT CO., LTD., Beijing (CN)

(72) Inventor: Fulai WANG, Beijing (CN)

(21) Appl. No.: 18/875,527

(22) PCT Filed: Jun. 16, 2023
(86) PCT No.: PCT/CN2023/100662

§ 371 Date: Dec. 16, 2024

(30) Foreign Application Priority Data
Jun. 27, 2022 (CN) 202210737334.1

(51) Int. Cl. H10P 72/76; C23C 16/458

(52) U.S. Cl. CPC H10P 72/7612; C23C 16/4586; H10P 72/7614; H10P 72/7624

(57) ABSTRACT

The present disclosure provides a processing chamber and semiconductor processing equipment, related to the semiconductor technology field, including a chamber body. The chamber body includes a base that ascends and descends, a plurality of lift pins, and a lift pin bracket. A plurality of lift pin holes are formed passing through the base in a vertical direction at the base. The plurality of lift pins are arranged at the lift pin bracket and inserted into the plurality of lift pin holes in a one-to-one correspondence. A guiding part extending in the vertical direction is arranged at the lower surface of the base. The guiding part is slidingly connected to the lift pin bracket. The guiding part ascends with the base and limits the position of the lift pin and cooperates with the lift pin bracket when a lower end of the guiding part contacts the lift pin bracket.

### TECHNICAL FIELD

The present disclosure generally relates to the semiconductor technology field and, more particularly, to a processing chamber and semiconductor processing equipment.

### BACKGROUND

In semiconductor processing equipment, Plasma Enhanced Chemical Vapor Deposition (PECVD) equipment is configured for a dielectric thin film deposition process to grow a dielectric thin film composed of Si, O, and N on a wafer (also configured for a thin film deposition process doped with B and P). Due to the special features of the PECVD process, the material of a lift pin is usually ceramic material. Since a base is used as an electrode plate, the base needs to be radio frequency conductive and made of a conductive material such as aluminum alloy or an AIN material with an internal metal electrode plate. Since a part of the lift pin is in the electrode plate and is made of ceramic insulation material, the lift pin causes the electric field to deform in the area of the lift pin. According to the capacitor principle, when the capacitance medium changes, the direction of the electric field line and the electric field strength can change as the medium changes. For example, the electric field line can curve, and the electric field strength can be weakened.

In the existing processing chamber, the cooperation between the lift pin and the base is shown in FIG. 1. To ensure that the lift pin 2 moves with the base 1 when the base 1 is lifted, an inverted cone shape position-limiting structure is arranged at the top of the lift pin 2. Thus, the area of the top end surface of the lift pin 2 can be relatively large, and the process uniformity in the wafter projection area corresponding to the lift pin 2 becomes poorer to impact the overall process uniformity of the wafer. In addition, for the cooperation between the lift pin 2 and the base 1 of the semiconductor processing equipment of the existing technology, due to the thermal expansion and contraction of the base 1, the base is cool during maintenance, and the outer periphery of the position-limiting structure is in contact with the hole wall of the inverted cone hole of the base 1. The lift pin 2 with the inverted cone shape position-limiting structure is easily stuck in the lift pin hole of the bases 1. The lift pin 2 is difficult to pull out.

### SUMMARY

The present disclosure provides a processing chamber and semiconductor processing equipment for the issue in the existing technology to solve the issue that the processing uniformity in the wafer projection area corresponding to the lift pin becomes poorer due to the large area at the top end surface of the lift pin of the existing technology, and the issue that the lift spin with the inverted cone position-limiting structure is stuck and difficult to be pulled out.

To realize the above purpose, the present disclosure provides a processing chamber, applied to the semiconductor processing equipment, including:
a chamber body, the chamber body including a base that ascends and descends, a plurality of lift pins, and a lift pin bracket;
wherein:
   a plurality of lift pin holes are formed passing through the base in a vertical direction at the base, the plurality of lift pins are arranged at the lift pin bracket and inserted into the plurality of lift pin holes in a one-to-one correspondence, a guiding part extending in the vertical direction is arranged at the lower surface of the base, the guiding part is slidingly connected to the lift pin bracket, and the guiding part ascends with the base and limits position of and cooperates with the lift pin bracket when a lower end of the guiding part contacts the lift pin bracket to cause the lift pin bracket and the plurality of lift pins to ascend with the guiding part; and
   when the base is at a transmission position, the lift pin bracket contacts a bottom wall of the chamber body, and the plurality of lift pins extend out from the upper surface of the base and are configured to support the wafer, and when the base is at a processing position, the lower end of the guiding part limits the position of and cooperates with the lift pin bracket, and top ends of the plurality of lift pins are not higher than the upper surface of the base.

In some embodiments, a lift pin hole of the plurality of the lift pin holes includes a fitting hole and a guiding hole arranged in sequence from top to bottom, a diameter of the fitting hole is smaller than a diameter of the guiding hole, a lift pin of the plurality of lift pins includes a fitting member and a guiding member arranged in sequence from top to bottom, the fitting member and the fitting hole have a clearance fit, and the guiding member and the guiding hole have a guiding fit.

In some embodiments, the fitting hole is transition-connected to the guiding hole by a first guiding cone surface, the fitting member is transition-connected to the guiding member by a second guiding cone surface, a diameter of an outer periphery annular surface of the second guiding cone surface and a diameter of an inner periphery annular surface of a first guiding cone surface increase from top to bottom, and the second guiding cone surface guides and cooperates with the first guiding cone surface.

In some embodiments, the diameter of the fitting member is not greater than 2 mm, and a diameter of the fitting hole can be not greater than 2.5 mm.

In some embodiments, a plurality of guiding parts are provided. The plurality of guiding parts are arranged along the circumference of the base at intervals. The lower end of the guiding part includes a position-limiting member protruding from an outer peripheral surface of the guiding part outwardly. The guiding part ascends with the base and limits the position of and cooperates with the lift pin bracket when the position-limiting member contacts the lift pin bracket.

In some embodiments, the lift pin bracket includes a support plate and a support structure. The support plate is slidingly connected to the guiding part. The guiding part ascends with the base and limits the position of the support plate and cooperates with the support plate when the lower end of the guiding part contacts the support plate. The plurality of lift pins are arranged at the support plate. A support structure is arranged on a side of the support plate away from the base. When the base is at the transmission position, the support structure contacts the bottom wall of the chamber body.

In some embodiments, the support structure includes a plurality of support columns. The plurality of support columns are arranged at a circumference of the support plate at intervals. When the base is at the transmission position, the plurality of the support columns contact the bottom wall of the chamber body.

In some embodiments, height adjustment assemblies are arranged at ends of the plurality of support columns away from the support plate. The plurality of height adjustment assemblies are configured to adjust heights of top ends of the plurality of lift pins relative to the upper surface of the base when the base is at the transmission position.

In some embodiments, a height adjustment assembly includes a sleeve screw and a locking nut. The sleeve screw is connected to a thread at the lower end of the support column. The sleeve screw is rotated to cause the support column threadedly connected to the sleeve screw to ascend and descend relative to the sleeve screw. The locking nut is threadedly connected to the support column. The locking nut is arranged above the sleeve screw and is configured to lock a relative position of the sleeve screw and the support column.

As another technical solution, the present disclosure provides semiconductor processing equipment, including the processing chamber of the present disclosure, a spray plate arranged at the top of the processing chamber, and a base ascending and descending mechanism arranged below the base. The base ascending and descending mechanism is configured to drive the base to ascend and descend between the transmission position and the processing position, and the spray plate is configured to spray a process gas in the processing chamber.

The present disclosure provides the processing chamber and the semiconductor processing equipment. The beneficial effects include as follows. The processing chamber can include the lift pin bracket. The lift pin bracket is guided by the guiding part. The lift pin bracket has a position limiting cooperation with the lower end of the guiding part. Thus, the lift pin bracket and the plurality of lift pins can ascend with the guiding part. When the base is at the processing position, the top ends of the plurality of lift pins can be no higher than the upper surface of the base. Meanwhile, since the lift pin bracket ascends with the guiding part, the lift pin bracket can always carry the lift pins. Thus, the position-limiting structure may not need to be arranged at the top of the lift pin. Thus, the area of the top end surface of the lift pin can become smaller, and the impact on the processing uniformity in the wafer projection area corresponding to the lift pin can be reduced to increase the overall processing uniformity of the wafer. Moreover, since the position-limiting structure is not arranged at the top of the lift pin in the processing chamber, the issue that the position-limiting structure is stuck in the base for the top of the lift pin due to the thermal expansion and contraction causes the lift pin to be difficult to pull out can be prevented.

Other features and advantages of the present disclosure are described in detail in the following embodiments of the present disclosure.

### BRIEF DESCRIPTION OF THE DRAWINGS

The exemplary implementation of the present disclosure is further described in more detail in connection with the accompanying drawings. The above and other objectives, features, and advantages of the present disclosure become more obvious. In the exemplary implementations of the present disclosure, the same reference numerals represent the same components.

FIG. 1 is a schematic diagram showing cooperation between a lift pin and a base of the existing semiconductor processing equipment.

FIG. 2 is a schematic structural diagram showing a lift pin of a processing chamber in a lift state according to an embodiment of the present disclosure.

FIG. 3 is a schematic structural diagram showing a lift pin of a processing chamber in a dropped state according to an embodiment of the present disclosure.

FIG. 4 is a schematic diagram showing a cooperation of a lift pin and a base of a processing chamber according to an embodiment of the present disclosure.

FIG. 5 is a schematic structural diagram of a lift pin of a processing chamber according to an embodiment of the present disclosure.

FIG. 6 is a schematic 3D diagram of a lift pin bracket and a support structure of a processing chamber according to an embodiment of the present disclosure.

FIG. 7 is a schematic front view structural diagram of a lift pin bracket and a support structure of a processing chamber according to an embodiment of the present disclosure.

FIG. 8 is a schematic cross-section structural diagram in direction A of FIG. 7.

FIG. 9 is a schematic diagram showing a comparison between projection areas of a lift pin of the present disclosure and a lift pin of the existing processing chamber on a wafer.

FIG. 10 is a schematic diagram showing a comparison between an electric field uniform distribution of the present disclosure and an electric field uniform distribution of the existing processing chamber in the comparison state of FIG. 9.

Reference numerals:

| | | | |
|---|---|---|---|
| 1 Base | 2 Lift pin | 3 Chamber body | 4 Support plate |
| 5 Support structure | | 6 Guiding part | 7 Position-limiting |
| | | | member |
| 8 Fitting hole | 9 Guiding hole | 10 Fitting member | 11 Guiding member |
| 12 First guiding cone | | | 13 Second guiding |
| surface member | | | cone surface member |
| 14 Support column | | 15 Sleeve screw | 16 Locking nut |
| 17 Spray plate | | 18 Ascending and | |
| | | descending column | |
| 19 Bellows | 20 Bottom wall | 21 Wafer | 22 Manipulator |

### DETAILED DESCRIPTION OF THE EMBODIMENTS

Preferred embodiments of the present disclosure are described in more detail. Although the preferred embodiments of the present disclosure are described below, it should be understood that the present disclosure can be implemented in various forms and should not be limited to the embodiments illustrated here. Instead, these embodiments are provided to make the present disclosure more thorough and complete and to fully convey the scope of the present disclosure to those skilled in the art.

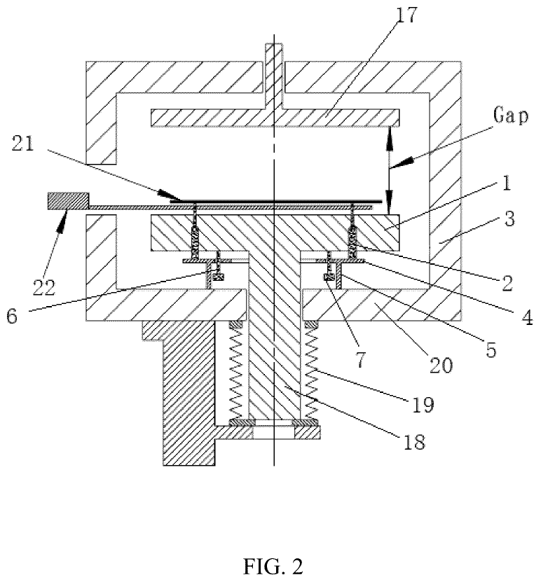

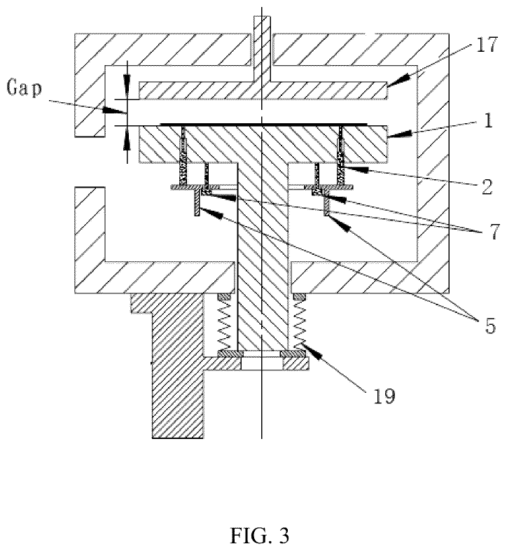

As shown in FIG. 2 and FIG. 3, the present disclosure provides a processing chamber applied to semiconductor processing equipment, including a chamber body 3.

The chamber body 3 includes a base 1 that can ascend and descend, a plurality of lift pins 2, and a lift pin bracket.

The base 1 includes a plurality of lift pin holes passing through the base 1 along a vertical direction. The plurality of lift pins can be arranged at the lift pin bracket and in a one-to-one correspondence with the plurality of lift pin holes. A guiding part 6 extending along the vertical direction can be arranged at the lower surface of the base 1. The guiding part 6 can be sliding-connected to the lift pin bracket and abut against the lower end of the guiding part 6. That is, the guiding part 6 can ascend with the base 1 and cooperate with the lift pin bracket when the lower end of the guiding part 6 is in contact with the lift pin bracket. Thus, the lift pin bracket and the plurality of lift pins 2 can ascend with the guiding part 6. Then, the lift pin bracket can carry the plurality of lift pins 2 when the base 1 ascends or descends to drive the plurality of lift pins 2 to ascend and descend with the base 1.

When the base 1 is at a transmission position, the lift pin bracket can be in contact with the bottom wall 20 of the chamber body 3. The plurality of lift pins 2 can extend out from the upper surface of the base 1 and can be configured to support the wafer 20. When the base 1 is at the processing position, the lower end of the guiding part 3 can cooperate with the lift pin bracket. The top end of the plurality of lift pins 2 may not be higher than the upper surface of the base 1.

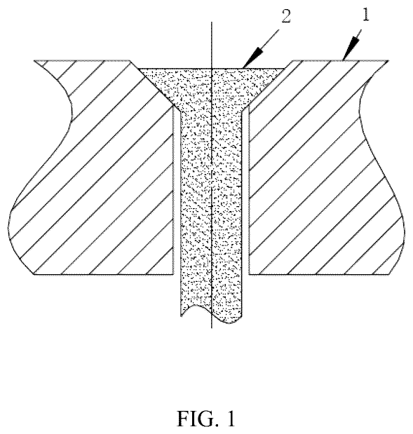

In some embodiments, in the existing semiconductor processing equipment, the cooperation between the lift pin 2 and the base 1 is shown in FIG. 1. To ensure the lift pin 2 to move with the base 1 when the base 1 ascends, an inverted cone-shaped position-limiting structure is arranged at the top of the lift pin 2 and forms a position-limiting cooperation with the inverted cone-shaped hole of the base 1. Thus, the area of the top surface of the lift pin 2 can be relatively large. Thus, the processing uniformity in the wafer projection area corresponding to the lift pin 2 can become poorer to further affect the overall processing uniformity of the wafer. In addition, for the cooperation between the lift pin 2 and the base 1 of the existing semiconductor processing equipment, due to the thermal expansion and contraction of the base 1, since the base 1 is cool during maintenance, and the outer periphery of the position-limiting structure is in contact with the hole wall of the inverted cone hole of the base 1, the lift pin 2 with the inverted cone-shaped position-limiting structure can be easily stuck in the lift pin hole of the base 1, and the lift pin 2 can be difficult to pull out.

To solve the issue that the processing uniformity of the wafer projection area corresponding to the lift pin 2 becomes poor due to the area of the top surface of the lift pin 2 being relatively large in the existing technology, the present disclosure provides a processing chamber. In the processing chamber, the lift pin bracket can be arranged below the base 1. In some embodiments, the lift bracket can include a guiding through-hole. The guiding part 6 can slidingly pass through the guiding through-hole. The guiding part 6 can guide the lift pin bracket to ensure that the lift bracket can slide vertically along the guiding part 6. A position-limiting member 7 protruding from the outer periphery of the guiding part 6 to the outer side can be arranged at the lower end of the guiding part 6. The outer radius of the position-limiting member 7 can be greater than the hole radius of the guiding through-hole. When the base 1 ascends to a certain height, the position-limiting member 7 can be in contact with the lower surface of the lift pin bracket. Thus, the position-limiting cooperation can be realized between the guiding part 6 and the lift pin bracket. Then, the guiding part 6, the lift pin bracket, and the base 1 can be relatively fixed and can ascend synchronously. The lift pin 2 can be slidingly arranged in the lift pin hole. Since the lift pin bracket can ascend with the guiding part 6, the lift pin bracket can always carry the lift pin 2. Thus, the position-limiting structure may not need at the top of the lift pin 2 to ensure the lift pin 2 to move with the base 1 when the base 1 ascends. Then, the area of the top end surface of the lift pin 2 can become smaller, and the impact on the processing uniformity in the projection area of the wafer 21 corresponding to the lift pin 2 can be reduced. The overall processing uniformity of the wafer 21 can be improved. In addition, since the position-limiting structure is not arranged at the top of the lift pin 2 in the processing chamber, the issue that the lift pin is difficult to pull out since the position-limiting structure at the top of the lift pin is stuck in the base 1 due to the thermal expansion and contraction can be prevented. In some embodiments, the lift pin 2 can be column-shaped or cone-shaped, and the lift pin hole can have a sliding cooperation with the lift pin 2 to guide the ascending and descending of the lift pin 2.

It should be noted, that in practical applications, the lower end of the guiding part 6 can have other structures that can have position-limiting cooperation with the lift pin bracket, which is not limited in embodiments of the present disclosure.

In some embodiments, the shape of the lift pin hole can match the shape of the lift pin 2. When the lift pin 2 is column-shaped, the lift pin hole can be a column-shaped hole. When the lift pin 2 is cone-shaped, the lift pin hole can be a cone-shaped hole. The hole wall of the cone-shaped hole can provide alignment guidance to the lift pin 2. That is, even if the lift pin 2 is off relative to the center of the lift pin hole, the lift pin 2 can be gradually aligned when the top end of the lift pin 2 passes out of the upper surface of the base 1. It should be noted that when the top end of the lift pin 2 is retracted back into the lift pin hole, the gap between the outer periphery of the top end of the lift pin 2 and the inner periphery of the lift pin hole may need to be prevented from being excessive. Since the cone-degrees of the cone-shaped hole and the lift pin 2 are relatively small. The gap between the outer periphery of the top end of the lift pin 2 and the inner periphery of the lift pin hole may need to be maintained to be smaller than 0.5 mm when the top end of the lift pin 2 is retracted back into the lift pin hole.

In some embodiments, the lift pin bracket can include a support plate 4 and a support structure 5. The support plate 4 can be slidingly connected to the guiding part 6. The guiding part 6 can ascend with the base 1 and form a position-limiting cooperation with the support plate 4 when the lower end of the guiding part 6 is in contact with the support plate 4. The plurality of lift pins 2 can be arranged at the support plate 4. The support structure 5 can be arranged on a side of the support plate away from the base 1. When the base 1 is in the transmission position, the support structure 5 can be in contact with the bottom wall 20 of the chamber body 3.

In some embodiments, when the base 1 is in the transmission position, the support structure 5 can be in contact with the bottom wall 20 of the chamber body 3. Then, the upper ends of the plurality of lift pins 2 can extend out from the upper side to lift the wafer 21. The guiding part 6 can provide guidance to the support plate 4 to realize the ascending and descending guidance to the lift pin 2.

In some embodiments, the support structure 5 can include a plurality of support columns 14. The plurality of support columns 14 can be arranged at intervals along the circumference of the support plate 4. When the base 1 is at the transmission position, the plurality of support columns 14 can be in contact with the bottom wall of the chamber body 3.

In some embodiments, the support columns 14 can form a column-shaped protrusion structure at the lower surface of the support plate 4 and can be configured to support the bottom wall 20 of the chamber body 3 after the base 1 descends to a certain height. The ascending and descending bracket and the base 1 can be caused to move relatively. Then, the lift pin 20 can be lifted to cause the lift pin 2 to ascend relative to the base 1 to lift the wafer 21 on the base 1.

In some embodiments, a plurality of guiding parts 6 can be provided. The plurality of guiding parts 6 can be arranged at intervals along the circumference of the base 1. A position-limiting member 7 protruding from the outer periphery of the guiding part 6 toward the outside can be provided on an end of the guiding part 6 away from the base 1. The guiding part 6 can ascend with the base 1 and can have position-limiting cooperation with the lift pin bracket when the position-limiting member 7 contacts the lift pin bracket. In some embodiments, when the base 1 is at the processing position, the support plate 4 can abut against the position-limiting member 7. That is, the guiding part 6 can ascend with the base 1 and have position-limiting cooperation with the support plate 4 when the position-limiting member 7 contacts the support plate 4.

In some embodiments, the guiding part 6 can be column-shaped. The position-limiting member 7 can be arranged at the outer periphery of the lower end of the guiding part 6 and can interfere with the hole wall of the guiding through-hole of the support plate 4 to limit the position of the support plate 4. When the base 1 ascends to a certain height, the position-limiting member 7 can contact the lower surface of the support plate 4 and form a snap connection to cause the base 1 to drive the support plate 4 to ascend.

In some embodiments, the lift pin hole can include a fitting hole 8 and a guiding hole 9 arranged in sequence from up to bottom. The hole radius of the fitting hole 8 can be smaller than a hole radius of the guiding hole 9. The lift pin 2 can include a cooperation member 10 and a guiding member 11 arranged in sequence from up to bottom. The cooperation member 10 can have a gap cooperation with the fitting hole 8, and the guiding member 11 can have a guiding cooperation with the guiding hole 9.

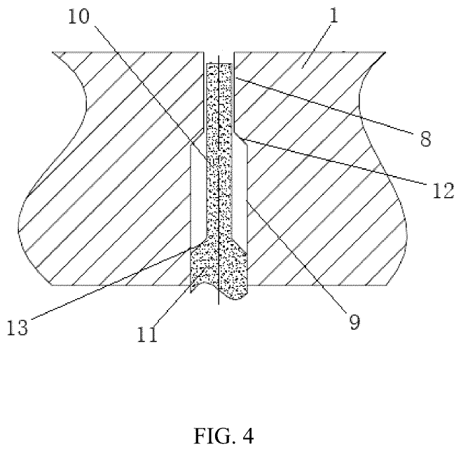

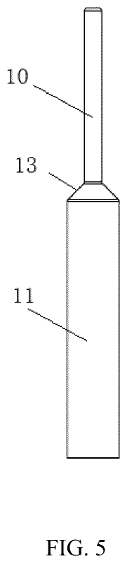

In some embodiments, as shown in FIG. 4 and FIG. 5, the lift pin hole can be a stepped hole. The lift pin 2 can be in a stepped column shape. The fitting member 10 of the lift pin 2 can slide in the cooperation hole 8. The guiding member 11 of the lift pin 2 can slide in the guiding hole 9. The fitting member 10 and the fitting hole 8 can have a gap cooperation. The guiding member 11 can have a sliding guide cooperation with the fitting hole 9 to ensure the guiding effect of the lift pin hole on the lift pin 2.

In some embodiments, the fitting hole 8 and the guiding hole 9 can be transitionally connected through the first guiding cone surface member 12. The fitting member 10 and the guiding member 11 can be transitionally connected through the second guiding cone surface member 13. The diameter of the outer periphery annular surface of the second guiding cone surface member 13 and the diameter of the inner periphery annular surface of the first guiding cone surface member 12 can be gradually increased from up to bottom, and the second guiding cone surface member 13 can have a guiding cooperation with the first guiding cone surface member 12.

In some embodiments, as shown in FIG. 4, the lift pin hole includes the first guiding cone surface member 12. The lift pin 2 includes the second guiding cone surface member 13. As the lift pin 2 ascends relative to the lift pin hole, the second guiding cone surface member 13 can gradually approach the first guiding cone surface member 12 until contacting the first guiding cone surface member 12. During this process, the first guiding cone surface member 12 can guide and align the second guiding cone surface member 13. Even if the lift pin 2 is off from the center of the lift pin hole, the lift pin 2 can be gradually aligned when the top end of the lift pin 2 passes through the upper surface of the base 1.

Further, for the cooperation between the lift pin 2 and the base 1 in the semiconductor processing equipment of the existing technology shown in FIG. 1, due to the thermal expansion and contraction of the base 1, when the base 1 is cool during maintenance and the outer periphery of the position-limiting structure contacts the hole wall of the inverted cone hole of the base 1, the lift pin 2 with the inverted cone position-limiting structure can be easily stuck in the lift pin hole of the base 1 and can be difficult to be pulled out. Thus, the fitting member 10 and the fitting hole 8 of the present disclosure can have a clearance fit with an F7/g6 shaft-hole fit tolerance. During maintenance, the cooperation between the lift pin 2 and the lift pin hole of the base 1 is shown in FIG. 4. The first guiding cone surface member 12 does not contact the second guiding cone surface member 13, and the lift pin bracket is removed. That is, the lift pin 2 can be easily removed from below the base 1, the lift pin 2 may not be stuck, and the maintainability of the equipment can be improved.

In some embodiments, the diameter of the fitting member 10 may not be greater than 2 mm, and the hole diameter of the fitting hole 8 may not be greater than 2.5 mm.

In some embodiments, the position-limiting structure may not need to be arranged at the top end of the lift pin 2. Thus, the diameter of the fitting member 10 at the top end of the lift pin 2 can be as small as possible. The diameter of the fitting member 10 may not be larger than 2 mm, and the diameter of the fitting hole 8 may not be larger than 2.5 mm. Compared to the inverted cone hole of the base 1 in the semiconductor processing equipment of the existing technology shown in FIG. 1, the size of the hole at the upper surface of the base 1 can be greatly reduced. Then, the area of the top end surface of the lift pin 2 in the projection area of the wafer 21 can be greatly reduced. The impact on the overall uniformity of the wafer 21 can be reduced.

In some embodiments, the diameter of the guiding member 11 of the lift pin 2 can be usually not greater than 10 mm.

In some embodiments, the diameter of the guiding member 11 can be larger than the diameter of the fitting member 10 to ensure the overall strength and rigidity of the lift pin 2 as much as possible.

In some embodiments, the support plate 4 can be annular, and the upper surface of the support plate 4 can be a flat surface.

In some embodiments, the support plate 4 can be configured to carry the lift pin 2. The upper surface of the support plate 4 can be a flat surface to ensure the plurality of lift pins 2 are on the same flat surface. Then, the heights of the lift pins 2 can be ensured to be consistent.

In some embodiments, a height adjustment assembly can be arranged at an end of each of the plurality of support columns 14 away from the support plate 4. The plurality of height adjustment assemblies can be configured to adjust the height of the top end of the plurality of lift pins 2 relative to the upper surface of the base 1 when the base 1 is at the transmission position.

In some embodiments, the height adjustment assembly can contact the bottom wall 20 of the chamber body 3 when the base 1 is at the transmission position. The height of the top end of the plurality of lift pins 2 relative to the upper surface of the base 1 can be adjusted through the plurality of height adjustment assemblies when the base 1 is at the transmission position. Thus, the plurality of lift pins 2 can be ensured to be at the same surface to ensure the heights of the lift pins 2 are consistent.

In some embodiments, the height adjustment assembly can include a sleeve screw 15 and a locking nut 16. The thread at the lower end of the support column 14 can be connected to the sleeve screw 15. Then, the sleeve screw 15 can be rotated to cause the support column 14 threadedly connected to the sleeve screw 15 to ascend and descend relative to the sleeve screw 15. The locking nut 16 can be threadedly connected to the support column 14. The locking nut 16 can be arranged above the sleeve screw 15 and can be configured to lock the relative position of the sleeve screw 15 and the support column 14.

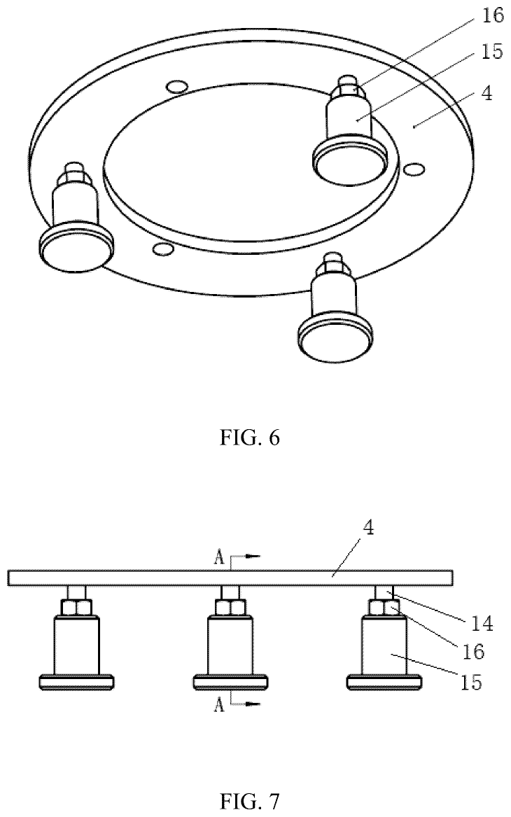

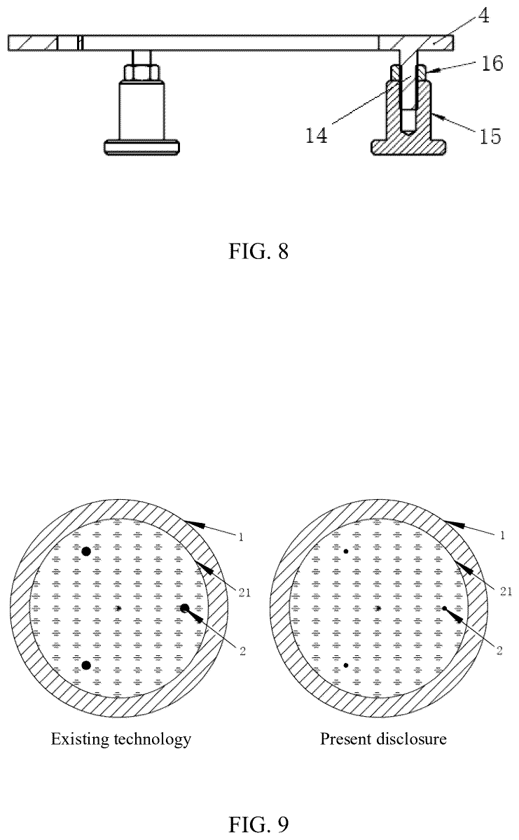

In some embodiments, as shown in FIG. 6 to FIG. 8, an outer thread is provided at the outer periphery of the lower end of the support column 14. The sleeve screw 15 is threadedly connected to the lower end of the support column 14. When the height of the lift pin 2 needs to be adjusted when the base 1 is in a wafer transmission state of the wafer 21, the sleeve screw 15 can be rotated to adjust the support height of the support plate 4 to the lift pin 2 to cause the lift pin 2 to ascend or descend. As shown in FIG. 6 to FIG. 8, a locking nut 16 is arranged at the support column 14 at the lower surface of the support plate 4. After the adjustment of the sleeve screw 15 is completed, the locking nut 16 can be locked to fix the position of the sleeve screw 15. Thus, the position of the sleeve screw 15 may not change with the ascending and descending situation, and the operation stability of the equipment can be improved.

As another technical solution, as shown in FIG. 2, embodiments of the present disclosure further provide the semiconductor processing equipment, including the processing chamber of embodiments of the present disclosure, a spray plate 17 arranged at the top of the processing chamber, and a base ascending and descending mechanism arranged below the base 1. The base ascending and descending mechanism can be configured to drive the base 1 to ascend and descend between the transmission position and the processes. The spray plate 17 can be configured to spray a process gas in the processing chamber.

In some embodiments, the base ascending and descending mechanism can include an ascending and descending column 18 and an ascending and descending drive structure. The ascending and descending column 18 can be connected below the base 1 and pass through the bottom wall of the chamber body 20 to extend toward the chamber body 3. The annular support plate 4 can be sleeved at the outer side of the ascending and descending columns 18. The portion of the ascending and descending column 18 on the outer side of the bottom wall 20 of the chamber body 3 can be sleeved by a bellows 19. The two ends of the bellows 19 can be sealedly connected to the lower side of the bottom wall 20 of the chamber body 3 and the outer periphery of the lower end of the ascending and descending column 18, respectively. The ascending and descending structure can be configured to drive the ascending and descending column 18 to ascend and descend to drive the base 1 and the wafer on the base 1 to ascend and descend. Thus, the wafer 21 can be away from or approach the spray plate 17.

In some embodiments, the base 1 can be a heating base and can be configured to heat the wafer 21 on the base 1.

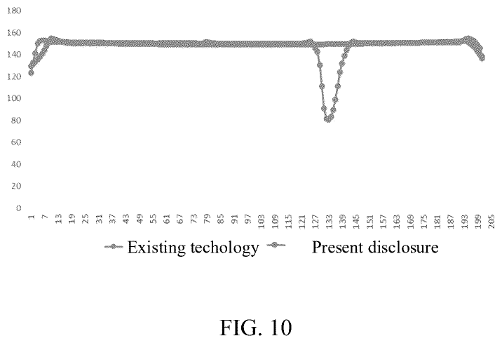

In summary, during the operation of the semiconductor processing equipment of embodiments of the present disclosure, in the initial state, the base 1 can be at a lower position (the position for transmitting the wafer 21). Then, the support structure 5 below the support plate 4 can be against the bottom wall 20 of the chamber body 3. Due to the support of the support plate 4, the fitting member 10 of the lift pin 2 can extend from the upper surface of the base 1, and the upper end surface of the fitting member 10 can be higher than the upper surface of the base 1 for a certain height. The manipulator 22 can transfer and place the wafer 21 on the upper surface of the fitting member 10 of the lift pin 2, and the manipulator can exit. Then, the ascending and descending mechanism of the base 1 can drive the base 1 to ascend. In the first phase, the lift pin 2 and the support plate 4 may not ascend. The top surface of the lift pin 2 can be lower than the upper surface of the base 1, and the wafer 21 can be carried by the base 1. When the position-limiting member 7 contacts the lower surface of the support plate 4, the equipment can enter the second phase. In the second phase, the lift pin 2 can be driven by the support plate 4 to ascend with the base 1, until the base 1 and the wafer 21 on the base 1 ascend to the position with the Gap required by the processing. Then, the processing can start. After the processing ends, the above process can be inverted. The manipulator 22 can eventually transfer the wafer 21 out. In the present disclosure, since the heating base is no longer configured to support the lift pin 2, the position-limiting structure may no longer be needed at the top of the lift pin 2 to ensure that the lift pin 2 can move with the base 1 together when the base 1 ascends. Thus, the area of the top end surface of the lift pin 2 can be reduced a lot, and the projection area of the top end surface of the lift pin 2 on the wafer 21 can be reduced, which is more beneficial for the uniform distribution of the electric field and to improve the overall processing uniformity of the wafer 21. FIG. 9 is a schematic diagram showing a comparison between the projection areas of the lift pin of the present disclosure and the lift pin of the existing processing chamber on the wafer 21. FIG. 10 is a schematic diagram showing a comparison between the electric field uniform distribution of the present disclosure and the electric field uniform distribution of the existing processing chamber in the comparison state of FIG. 9. In the present disclosure, the electric field uniformity of the semiconductor processing equipment can be optimized.

Embodiments of the present disclosure are described. The above description is exemplary, not exhaustive and is not limited to the disclosed embodiments. Without departing from the scope and spirit of embodiments of the present disclosure, modifications and variations to the embodiments of the present disclosure can be obvious to those ordinary skill in the art.

1. A processing chamber, applied to semiconductor processing equipment, comprising:
a chamber body including a base that ascends and descends, a plurality of lift pins, and a lift pin bracket;
wherein:
a plurality of lift pin holes are formed passing through the base in a vertical direction at the base, the plurality of lift pins are arranged at the lift pin bracket and inserted into the plurality of lift pin holes in a one-to-one correspondence, a guiding part extending in the vertical direction is arranged at the lower surface of the base, the guiding part is slidingly connected to the lift pin bracket, and the guiding part ascends with the base and limits position of and cooperates with the lift pin bracket when a lower end of the guiding part contacts the lift pin bracket to cause the lift pin bracket and the plurality of lift pins to ascend with the guiding part; and
when the base is at a transmission position, the lift pin bracket contacts a bottom wall of the chamber body, and the plurality of lift pins extend out from the upper surface of the base and are configured to support the wafer, and when the base is at a processing position, the lower end of the guiding part limits the position of and cooperates with the lift pin bracket, and top ends of the plurality of lift pins are not higher than the upper surface of the base.

2. The processing chamber according to claim 1, wherein a lift pin hole of the plurality of the lift pin holes includes a fitting hole and a guiding hole arranged in sequence from top to bottom, a diameter of the fitting hole is smaller than a diameter of the guiding hole, a lift pin of the plurality of lift pins includes a fitting member and a guiding member arranged in sequence from top to bottom, the fitting member and the fitting hole have a clearance fit, and the guiding member and the guiding hole have a guiding fit.

3. The processing chamber according to claim 2, wherein the fitting hole is transition-connected to the guiding hole by a first guiding cone surface, the fitting member is transition-connected to the guiding member by a second guiding cone surface, a diameter of an outer periphery annular surface of the second guiding cone surface and a diameter of an inner periphery annular surface of a first guiding cone surface increase from top to bottom, and the second guiding cone surface guides and cooperates with the first guiding cone surface.

4. The processing chamber according to claim 2, wherein the diameter of the fitting member is smaller than or equal to 2 mm, and a diameter of the fitting hole is smaller than or equal to 2.5 mm.

5. The processing chamber according to claim 1, wherein a plurality of guiding parts are provided, the plurality of guiding parts are arranged along a circumference of the base at intervals, the lower end of the guiding part includes a position-limiting member protruding from an outer peripheral surface of the guiding part outwardly, and the guiding part ascends with the base and limits the position of and cooperates with the lift pin bracket when the position-limiting member contacts the lift pin bracket.

6. The processing chamber according to claim 1, wherein the lift pin bracket includes a support plate and a support structure, the support plate is slidingly connected to the guiding part, the guiding part ascends with the base and limits the position of and cooperates with the support plate when the lower end of the guiding part contacts the support plate, the plurality of lift pins are arranged at the support plate, a support structure is arranged on a side of the support plate away from the base, and when the base is at the transmission position, the support structure contacts the bottom wall of the chamber body.

7. The processing chamber according to claim 6, wherein the support structure includes a plurality of support columns arranged at a circumference of the support plate at intervals, and when the base is at the transmission position, contacting the bottom wall of the chamber body.

8. The processing chamber according to claim 7, wherein height adjustment assemblies are arranged at ends of the plurality of support columns away from the support plate, and configured to adjust heights of top ends of the plurality of lift pins relative to the upper surface of the base when the base is at the transmission position.

9. The processing chamber according to claim 8, wherein a height adjustment assembly includes:
a sleeve screw connected to a thread at the lower end of the support column and rotated to cause the support column threadedly connected to the sleeve screw to ascend and descend relative to the sleeve screw; and
a locking nut is threadedly connected to the support column, arranged above the sleeve screw, and configured to lock a relative position of the sleeve screw and the support column.

10. Semiconductor processing equipment comprising:
a processing chamber including:
a chamber body including a base that ascends and descends, a plurality of lift pins, and a lift pin bracket;
wherein:
a plurality of lift pin holes are formed passing through the base in a vertical direction at the base, the plurality of lift pins are arranged at the lift pin bracket and inserted into the plurality of lift pin holes in a one-to-one correspondence, a guiding part extending in the vertical direction is arranged at the lower surface of the base, the guiding part is slidingly connected to the lift pin bracket, and the guiding part ascends with the base and limits position of and cooperates with the lift pin bracket when a lower end of the guiding part contacts the lift pin bracket to cause the lift pin bracket and the plurality of lift pins to ascend with the guiding part; and
when the base is at a transmission position, the lift pin bracket contacts a bottom wall of the chamber body, and the plurality of lift pins extend out from the upper surface of the base and are configured to support the wafer, and when the base is at a processing position, the lower end of the guiding part limits the position of and cooperates with the lift pin bracket, and top ends of the plurality of lift pins are not higher than the upper surface of the base;
a spray plate arranged at the top of the processing chamber and configured to spray a process gas in the processing chamber; and
a base ascending and descending mechanism arranged below the base and configured to drive the base to ascend and descend between the transmission position and the processing position.

11. The equipment according to claim 10, wherein a lift pin hole of the plurality of the lift pin holes includes a fitting hole and a guiding hole arranged in sequence from top to bottom, a diameter of the fitting hole is smaller than a diameter of the guiding hole, a lift pin of the plurality of lift pins includes a fitting member and a guiding member arranged in sequence from top to bottom, the fitting member and the fitting hole have a clearance fit, and the guiding member and the guiding hole have a guiding fit.

12. The equipment according to claim 11, wherein the fitting hole is transition-connected to the guiding hole by a first guiding cone surface, the fitting member is transition-connected to the guiding member by a second guiding cone surface, a diameter of an outer periphery annular surface of the second guiding cone surface and a diameter of an inner periphery annular surface of a first guiding cone surface increase from top to bottom, and the second guiding cone surface guides and cooperates with the first guiding cone surface.

13. The equipment according to claim 11, wherein the diameter of the fitting member is smaller than or equal to 2 mm, and a diameter of the fitting hole is smaller than or equal to 2.5 mm.

14. The equipment according to claim 10, wherein a plurality of guiding parts are provided, the plurality of guiding parts are arranged along a circumference of the base at intervals, the lower end of the guiding part includes a position-limiting member protruding from an outer peripheral surface of the guiding part outwardly, and the guiding part ascends with the base and limits the position of and cooperates with the lift pin bracket when the position-limiting member contacts the lift pin bracket.

15. The equipment according to claim 10, wherein the lift pin bracket includes a support plate and a support structure, the support plate is slidingly connected to the guiding part, the guiding part ascends with the base and limits the position of and cooperates with the support plate when the lower end of the guiding part contacts the support plate, the plurality of lift pins are arranged at the support plate, a support structure is arranged on a side of the support plate away from the base, and when the base is at the transmission position, the support structure contacts the bottom wall of the chamber body.

16. The equipment according to claim 15, wherein the support structure includes a plurality of support columns arranged at a circumference of the support plate at intervals, and when the base is at the transmission position, contacting the bottom wall of the chamber body.

17. The equipment according to claim 16, wherein height adjustment assemblies are arranged at ends of the plurality of support columns away from the support plate, and configured to adjust heights of top ends of the plurality of lift pins relative to the upper surface of the base when the base is at the transmission position.

18. The equipment according to claim 17, wherein a height adjustment assembly includes:
a sleeve screw connected to a thread of the support column and rotated to cause the support column threadedly connected to the sleeve screw to ascend and descend relative to the sleeve screw; and
a locking nut threadedly connected to the support column, arranged above the sleeve screw, and configured to lock a relative position of the sleeve screw and the support column.
